(19) United States
(12) Patent Application Publication
(10) Pub. No.: US 2026/0110713 A1
(43) Pub. Date: Apr. 23, 2026

(54) CURRENT SENSOR

(71) Applicant: Asahi Kasei Microdevices Corporation, Tokyo (JP)

(72) Inventors: Masato INOUE, Tokyo (JP); Toshiaki KAWASAKI, Tokyo (JP)

(21) Appl. No.: 19/319,735

(22) Filed: Sep. 5, 2025

(30) Foreign Application Priority Data
Oct. 21, 2024 (JP) 2024-184696

(51) Int. Cl. G01R 15/20

(52) U.S. Cl. CPC G01R 15/207

(57) ABSTRACT

The current sensor includes: a conductor 40 having a turn portion 43, first and second body portions 42a, 42b which connect one end and another end of the turn portion to the first and second terminal portions; and the first and second body portions include parallel sections 44a, 44b which are provided with at least one hole, and in a continuous cross section of the conductor which perpendicularly intersects an inner contour surface of the conductor, a cross-sectional area of a continuous cross section defined between the inner contour surface of the conductor in the parallel section and an inner surface of a hole positioned closest to an inner contour surface side of the conductor, is smaller than a cross-sectional area of another continuous cross section between the inner contour surface of the conductor outside the parallel section and an outer contour surface of the conductor.

The contents of the following patent application(s) are incorporated herein by reference:
NO. 2024-184696 filed in JP on Oct. 21, 2024.

### BACKGROUND

### 1. Technical Field

The present invention relates to a current sensor.

### 2. Related Art

A current sensor in which a conductor through which the current to be measured flows and a magnetoelectric conversion element close to the conductor are encapsulated in a package; and the magnetoelectric conversion element is used to detect a strength of a magnetic field that is generated by the current to be measured flowing through the conductor and convert it into an electrical signal, thereby detecting an amount of current, is known. In such a current sensor, in order to enhance the detection sensitivity by concentrating the magnetic field on the magnetoelectric conversion element, a cross-sectional area of a conductor portion that is close to the magnetoelectric conversion element inside the package, is set to be smaller than a cross-sectional area of a conductor portion that is positioned on a periphery of the package, thereby increasing a current density in the conductor. In this manner, when an instantaneous overcurrent (for example, with a high frequency component of 1 MHz) flows due to a fault or the like in a system which is set as a measuring target for the current sensor, the conductor inside the package is excessively heated up and is melted and broken, thereby making it possible for the current sensor to function as a fuse. Patent Document 1 discloses a pyrotechnic disconnect that cuts off the conductor in response to the overcurrent and prevents a further damage by discharging an electric arc which occurs at that time, to a splitter side. In this way, it is desirable for the current sensor to function as the fuse when the overcurrent flows and not to damage a primary circuit and a secondary circuit.

### RELATED ART DOCUMENTS

### Patent Document

Patent document 1: International Publication No. WO 2017/136221

### GENERAL DISCLOSURE

In a first aspect of the present invention, there is provided a current sensor including: a conductor having a first terminal portion for inputting a current, and a second terminal portion for outputting the current which are arranged on one side in a first axial direction, the second terminal portion being spaced apart from the first terminal portion in a second axial direction intersecting the first axial direction, a turn portion which is arranged on another side with respect to the first terminal portion in the first axial direction, a first body portion which connects one end of the turn portion to the first terminal portion, and a second body portion which is spaced apart from the first body portion in the second axial direction, to connect another end of the turn portion to the second terminal portion; a magnetic sensor which is arranged on the conductor or near the conductor; and a package which encapsulates the turn portion, the first body portion, and the second body portion of the conductor, and the magnetic sensor, and which exposes the first terminal portion and the second terminal portion, in which at least one of the first body portion or the second body portion includes a parallel section which is provided with at least one hole, and when viewed from a third direction intersecting each of the first axial direction and the second axial direction, in a continuous cross section of the conductor which perpendicularly intersects an inner contour surface of the conductor, a cross-sectional area of a first continuous cross section that is defined between the inner contour surface of the conductor in the parallel section, and an inner surface of a hole of the at least one hole which is positioned closest to an inner contour surface side of the conductor, is smaller than a cross-sectional area of another continuous cross section between the inner contour surface of the conductor outside the parallel section and an outer contour surface of the conductor.

In a second aspect of the present invention, there is provided a current sensor including: a conductor having a first terminal portion for inputting a current, and a second terminal portion for outputting the current which are arranged on one side in a first axial direction, the second terminal portion being spaced apart from the first terminal portion in a second axial direction intersecting the first axial direction, a turn portion which is arranged on another side with respect to the first terminal portion in the first axial direction, a first body portion which connects one end of the turn portion to the first terminal portion, and a second body portion which is spaced apart from the first body portion in the second axial direction, to connect another end of the turn portion to the second terminal portion; a magnetic sensor which is arranged on the conductor or near the conductor; and a package which encapsulates the turn portion, the first body portion, and the second body portion of the conductor, and the magnetic sensor, and which exposes the first terminal portion and the second terminal portion, in which at least one of the first body portion or the second body portion includes a parallel section which is provided with at least one hole, and when viewed from a third direction intersecting each of the first axial direction and the second axial direction, for a cross section made in a manner that from an inner contour line of the conductor, a straight line perpendicularly intersecting the contour line is drawn to a point of first intersecting another contour line of the conductor, a dimension of a cross section in the parallel section is smaller than a dimension of a cross section at a part of the conductor outside the parallel section; and for a cross section made in a manner that from the inner contour line of the conductor, a straight line perpendicularly intersecting the contour line is drawn to an outer contour line of the conductor, there exists, at a part of the conductor outside the parallel section, a cross section which has a dimension with a value smaller than a total value of dimensions of a plurality of cross sections in the parallel section.

The summary clause does not necessarily describe all necessary features of the embodiments of the present invention. In addition, the present invention may also be a sub-combination of the features described above.

### BRIEF DESCRIPTION OF THE DRAWINGS

FIG. 1 shows an internal configuration of a current sensor according to the present embodiment, in a top view.

FIG. 2A shows a schematic configuration of a sensor unit.

FIG. 2B shows a definition of rectangularity.

FIG. 3A shows a definition of a shape and a size of a conductor (a width of the conductor and a width of an internal region) for a simulation.

FIG. 3B shows an analysis result of a density distribution of a surge current (1 MHz) flowing through the conductor.

FIG. 3C shows an analysis result of an amount of heat generation (average Joule heat) due to the surge current flowing through the conductor, with respect to the width of the conductor.

FIG. 4A shows a definition of a shape and a size of the conductor (a width of the conductor, a width of an internal region, and a position of a hole) for a simulation.

FIG. 4B shows an analysis result of an amount of heat generation (average Joule heat) due to a current flowing through the conductor, with respect to the position of the hole in the conductor.

FIG. 5A shows the surge current that is concentrated and flowing inside the conductor due to a proximity effect.

FIG. 5B shows a DC current flowing and spreading through the entire conductor.

FIG. 6A shows a fuse operation of the conductor (a first phase).

FIG. 6B shows a fuse operation of the conductor (a second phase).

FIG. 7A shows a definition of a shape and a size of the conductor (a width of the conductor, a width of an internal region, a position of a hole, and a width of a slit) for a simulation.

FIG. 7B shows an analysis result of an amount of heat generation (average Joule heat) due to the current flowing through the conductor, with respect to the width of the slit in the conductor.

FIG. 8 shows an internal configuration of the current sensor having a fault sensing function, in the top view.

FIG. 9 shows an arrangement of the conductor, a dielectric layer, and a magnetic sensor, in the top view.

FIG. 10A shows a configuration of a mounting substrate on which the current sensor is mounted, in the top view.

FIG. 10B shows an arrangement of the current sensor and a footprint, in the top view.

FIG. 11A shows a configuration of the current sensor according to a first modified example, in the top view.

FIG. 11B shows a configuration of the current sensor according to a second modified example, in the top view.

FIG. 11C shows a configuration of the current sensor according to a third modified example, in the top view.

FIG. 11D shows a configuration of the current sensor according to a fourth modified example, in the top view.

FIG. 11E shows a configuration of the current sensor according to a fifth modified example, in the top view.

FIG. 11F shows a configuration of the current sensor according to a sixth modified example, in the top view.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to the solution of the invention.

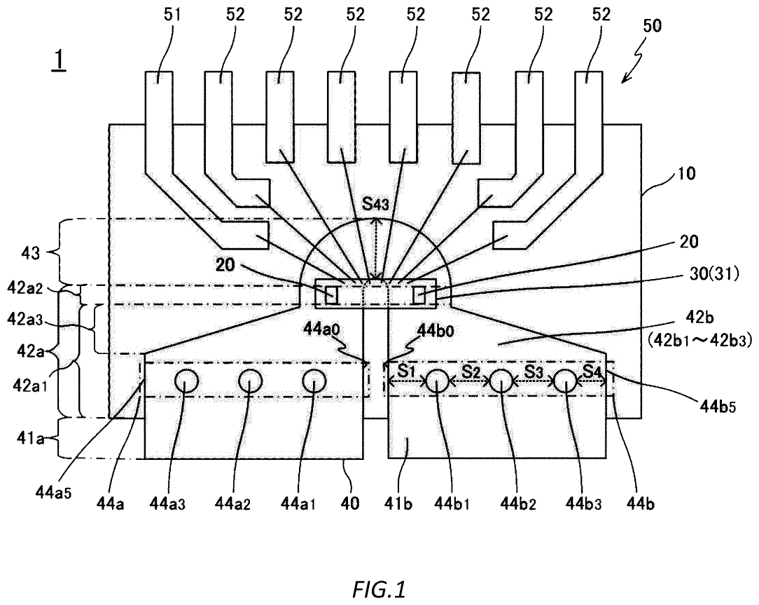

FIG. 1 shows an internal configuration of a current sensor 1 according to the present embodiment, in a top view in which a package 10 is seen through. Here, an up and down direction in the figure is defined as a vertical direction, and a right and left direction is defined as a horizontal direction, and a direction intersecting each of these two directions is defined as a height direction. The current sensor 1 is a sensor which: measures a current amount of a current to be measured by detecting a magnetic field that is generated around a conductor 40 by the current to be measured flowing through the conductor 40; and includes the package 10, a magnetic sensor 30, the conductor 40, and a plurality of signal terminals 50. It should be noted that in the present specification, the terms of a “contour surface” and a “contour line” are used for the conductor 40, where the contour surface refers to an outer front surface that forms a contour (an external shape) of the conductor 40, or a part thereof, and the contour line refers to an outer shape line that forms a contour (a shape) of the conductor 40 in the top view (a height direction view).

The package 10 is a member which protects each portion in the configuration of the current sensor 1; encapsulates a turn portion 43, a first body portion 42a, and a second body portion 42b in the conductor 40, the magnetic sensor 30, and a base end side of the plurality of signal terminals 50; and exposes a first terminal portion 41a and a second terminal portion 41b from a side surface on one side (a lower side of the figure) of the vertical direction, and exposes edges of the plurality of signal terminals 50 from a side surface on another side (an upper side of the figure) of the vertical direction. The package 10 is molded into a rectangular parallelepiped of a flat shape by mold forming, for example, by using encapsulating resin with an excellent insulation property, such as epoxy.

The magnetic sensor 30 is a sensor which detects the magnetic field that is generated by the current to be measured flowing through the conductor 40, and includes a substrate 31 and two sensor units 20. The magnetic sensor 30 is arranged on the conductor 40. It should be noted that the magnetic sensor 30 is set to include two sensor units 20, but instead of this, may include only one sensor unit.

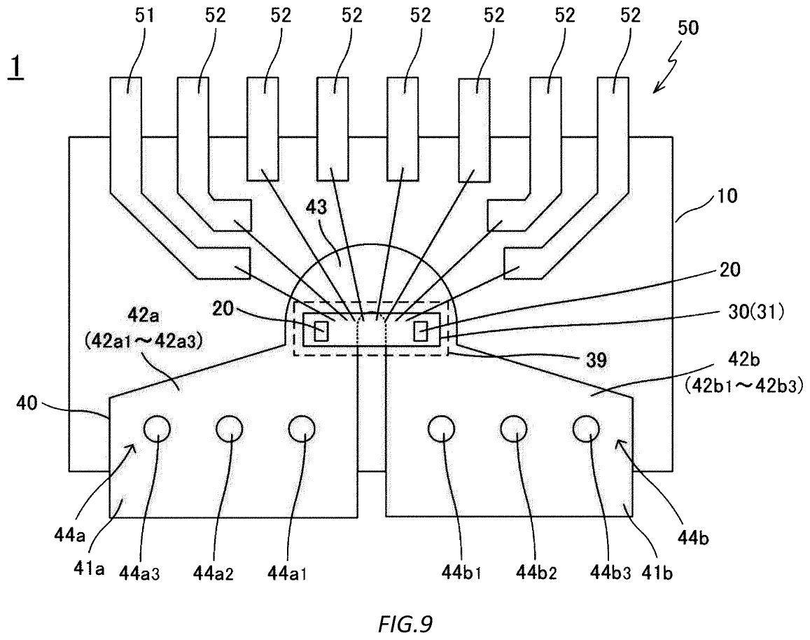

The substrate 31 is a member of a plate shape which is arranged on the conductor 40 via a dielectric layer 39 (refer to FIG. 9), and supports the two sensor units 20. The substrate 31 has, on an upper surface, a plurality of wirings (not shown) laid to be connected to the sensor unit 20. The substrate 31 is formed, for example, by using any of silicon (Si), gallium arsenide (GaAs), gallium nitride (GaN), aluminum nitride (AlN), sapphire (Si₂O₃), silicon carbide (SiC), or diamond.

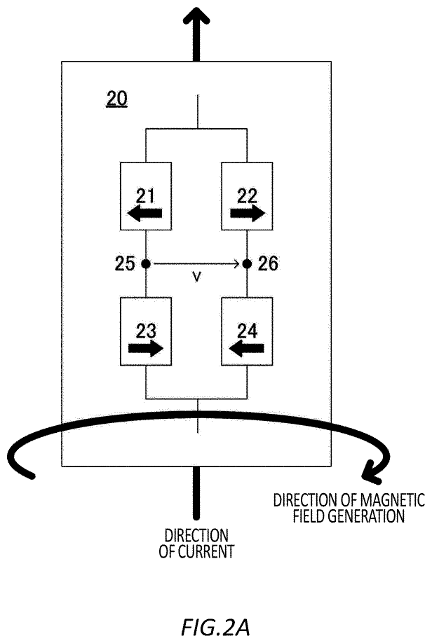

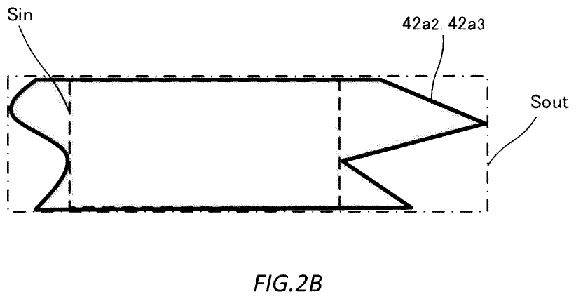

FIG. 2A shows a schematic configuration of the sensor unit 20. The sensor unit 20 is a circuit which changes an output voltage according to a magnetic flux density; and includes a plurality of (four in the present example) magnetoelectric conversion elements 21, 22, 23, 24 assembled in a shape of a Wheatstone ridge (full-bridge) circuit. It should be noted that the two magnetoelectric conversion elements 21 and 23, or 22 and 24 may be used to be assembled in a shape of a half-bridge circuit.

The plurality of magnetoelectric conversion elements 21, 22, 23, 24 are elements of which electrical characteristics (that is, magnetic resistances) change by a strength of the magnetic field that is applied. The magnetoelectric conversion elements 21, 22, 23, 24 are arranged with each of magnetic sensitive directions being oriented toward the horizontal direction, so as to detect a horizontal magnetic field that is generated on the conductor 40 by the current to be measured flowing through the conductor 40 in a direction of an arrow. Note that the magnetic sensitive directions of the magnetoelectric conversion elements 21, 24 are the same direction as each other; and the magnetic sensitive directions of the magnetoelectric conversion elements 22, 23 are the same direction as each other, and are directions opposite to the magnetic sensitive directions of the magnetoelectric conversion elements 21, 24. As the plurality of magnetoelectric conversion elements 21, 22, 23, 24, it is possible to adopt any element of a tunnel magnetoresistance element (TMR), a giant magnetoresistance element (GMR), or an anisotropic magnetoresistance element (AMR). For these elements, it is possible to use alloys containing, for example, at least one of Co, Fe, B, Ni, or Si, and more specifically, cobalt iron (CoFe), cobalt iron boron (CoFeB), and nickel iron (NiFe). By using these elements, it is possible to precisely measure the magnetic field that is generated by the current flowing through the conductor 40.

An output voltage V is a differential voltage between a terminal 25 between the magnetoelectric conversion elements 21 and 23, and a terminal 26 between the magnetoelectric conversion elements 22 and 24; and magnetic resistances R1, R2, R3, R4 of the respective magnetoelectric conversion elements 21, 22, 23, 24 are used to establish V∝R1×R4−R2×R3. This makes it possible for the magnetic sensor 30 to measure the strength of the magnetic field generated by the current to be measured flowing through the conductor 40.

The two sensor units 20 are respectively arranged in: the first body portion 42a (a first main body portion 42a₁ which is connected to the first terminal portion 41a, and a first connection portion 42a₂ which is connected to one end of the turn portion 43): and the second body portion 42b (a second main body portion 42b₁ which is connected to the second terminal portion 41b and a second connection portion 42b₂ which is connected to another end of the turn portion 43). These connection portions have rectangular shapes in the top view as described below, and the sensor unit 20 is arranged on top of them, thereby making it possible to concentrate, on the sensor unit 20, the magnetic field in the horizontal direction that is generated by energizing the conductor 40, and to detect the amount of current with high sensitivity. It should be noted that the sensor unit 20 may be arranged only on one of the first connection portion 42a₂ or the second connection portion 42b₂. The first connection portion 42a₂ and the second connection portion 42b₂ may be set to have a rectangular shape or an approximately rectangular shape in the top view.

FIG. 2B shows a definition of rectangularity that represents degrees of rectangular shape of the first connection portion 42a₂ and the second connection portion 42b₂. Contour lines of the first connection portion 42a₂ and the second connection portion 42b₂ are set to be represented by solid lines. For two parallel sides extending in the horizontal direction and two parallel sides extending in the vertical direction, which form a rectangular shape, the rectangularity Sin/Sout is defined by using an area Sin of a rectangular region with a greatest area that is arranged inside the contour lines of the first connection portion 42a₂ and the second connection portion 42b₂, and an area Sout of a rectangular region with a smallest area that is arranged outside the contour lines of the first connection portion 42a₂ and the second connection portion 42b₂. A true rectangular shape has rectangularity of 1, and an approximately rectangular shape has rectangularity of 0.8 or more and less than 1. The first connection portion 42a₂ and the second connection portion 42b₂ may have approximately rectangular shapes without being limited to the rectangular shape in the top view, whereby it becomes easy to mold a lead frame when the conductor 40 is manufactured, and it becomes easy for the conductor 40 to be adhered to the package 10, and it is possible to prevent peeling off between them.

It should be noted that the sensor unit 20 may be configured by using a Hall element, and may be arranged inside the turn portion 43 or near the conductor 40 to detect a vertical magnetic field that is generated by the current flowing through the conductor 40.

The conductor (also referred to as a bus bar) 40 is a conductive member which is arranged on one side (the lower side of the figure) in the vertical direction in the package 10, and which forms a current path through which the current to be measured flows; and has the first terminal portion 41a, the second terminal portion 41b, the first body portion 42a, the second body portion 42b, and the turn portion 43. It should be noted that a thickness of the conductor 40 is approximately constant.

The first terminal portion 41a is a terminal for inputting the current to be measured (also simply referred to as the current). The first terminal portion 41a is arranged on one side (the lower side of the figure) in the vertical direction, and protrudes from a side surface of the package 10 on the lower side of the figure.

The second terminal portion 41b is a terminal for outputting the current. The second terminal portion 41b is arranged to be spaced apart from the first terminal portion 41a in the horizontal direction (a right side of the figure) in the figure, and protrudes from the side surface of the package 10 on the lower side of the figure. It should be noted that the second terminal portion 41b may be used as the terminal for inputting the current, and the first terminal portion 41a may be used as the terminal for outputting the current.

The first body portion 42a is a portion that connects one end of the turn portion 43 to the first terminal portion 41a. The first body portion 42a includes the first main body portion 42a₁ and the first connection portion 42a₂ which are respectively positioned on a first terminal portion 41a side and a turn portion 43 side. The first main body portion 42a₁ has a tapering shape portion 42a₃ which increases in a cross-sectional area, from a connection portion (the first connection portion 42a₂) with the turn portion 43, toward the first terminal portion 41a side; and includes a parallel section 44a in which at least one hole 44aᵢ (i=1 to I, where I is 3 in the present example) is provided laterally in the horizontal direction in a lower part of the figure (a first terminal portion side), where the cross-sectional area is maximized in the tapering shape portion. The first connection portion (also referred to as a first arm portion) 42a₂ has a rectangular shape for being connected to the turn portion 43 in the top view, and the sensor unit 20 of the magnetic sensor 30 is arranged on it. It should be noted that the cross-sectional area of the tapering shape portion 42a₃ is a cross-sectional area of a cross section of the tapering shape portion 42a₃, which perpendicularly intersects an inner contour surface 44a₀ of the conductor 40.

The second body portion 42b is a portion that connects another end of the turn portion 43 to the second terminal portion 41b, and is arranged to be spaced apart from the first body portion 42a in the horizontal direction (in the right side of the figure). The second body portion 42b includes the second main body portion 42b₁ and the second connection portion 42b₂ which are respectively positioned on a second terminal portion 41b side and the turn portion 43 side. The second main body portion 42b₁ has a tapering shape portion 42b₃ which increases in a cross-sectional area, from a connection portion (the second connection portion 42b₂) with the turn portion 43, toward the second terminal portion 41b side; and includes a parallel section 44b in which at least one hole 44bᵢ (i=1 to I, where I is 3 in the present example) is provided laterally in the horizontal direction in a lower part of the figure (a second terminal portion side), where the cross-sectional area is maximized in the tapering shape portion. The second connection portion (also referred to as a second arm portion) 42b₂ has a rectangular shape for being connected to the turn portion 43 in the top view, and the sensor unit 20 of the magnetic sensor 30 is arranged on it. It should be noted that the cross-sectional area of the tapering shape portion 42b₃ is a cross-sectional area of a cross section of the tapering shape portion 42b₃, which perpendicularly intersects an inner contour surface 44b₀ of the conductor 40.

The turn portion 43 is a portion that: is connected to the two body portions 42a, 42b at both ends; is arranged on another side (the upper side of the figure) in the vertical direction; extends from one side (the lower side of the figure) in the vertical direction to the another side (the upper side of the figure); has a shape of bending and returning to one side in the horizontal direction; and has an approximately circular arc shape, as an example. It should be noted that the turn portion 43 may be bent to have a U shape, an inverted V shape, or an n shape. In the turn portion 43, the current to be measured is input from the first body portion 42a, and the current to be measured is output to the second body portion 42b.

By including the first terminal portion 41a, the second terminal portion 41b, the first body portion 42a, the second body portion 42b, and the turn portion 43 which are formed as described above, the conductor 40 has an approximately U shape that: runs through an inside of the package 10, from the first terminal portion 41a provided on a left side of the figure, on the side surface of the package 10 on the lower side of the figure; returns to the lower side of the figure; and reaches to the second terminal portion 41b provided on a right side of the side surface on the lower side of the figure. It is possible to use conductive metal such as, for example, copper to form the conductor 40.

The plurality of signal terminals 50 are members for transmitting the output signal of the magnetic sensor 30 to a secondary circuit 3; are spaced apart from the conductor 40 to the upper side of the figure; are arrayed in the horizontal direction; and are encapsulated in the package 10 with the edges being exposed from a side surface on the upper side of the figure. It is possible to use conductive metal such as, for example, copper to form the plurality of signal terminals 50. The plurality of signal terminals 50 are bonded to the magnetic sensor 30 by wiring. It should be noted that an edge portion exposed from the package 10 is connected to the secondary circuit 3 on a mounting substrate 100 when the current sensor 1 is mounted on the mounting substrate 100.

The conductor 40 has electrical resistance that is slight though, and thus Joule heating occurs when the current flows through it. Here, when an instantaneous overcurrent (referred to as a surge current) that may occur during a fault flows through the conductor 40, the surge current contains a high frequency component of 1 MHz or more, for example, and thus the current density is concentrated on a front surface of the conductor 40 due to a skin effect. Further, when the current flows in a reverse direction between adjacent conductors, such as the first body portion 42a and the second body portion 42b, the current density is concentrated on sides that are close to each other due to a proximity effect.

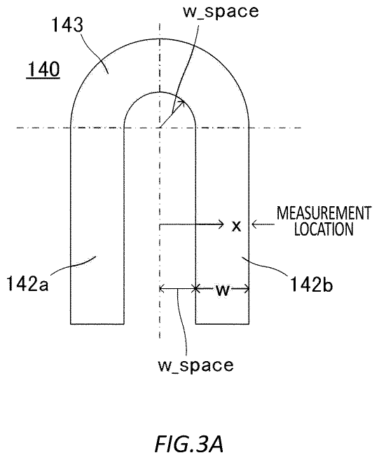

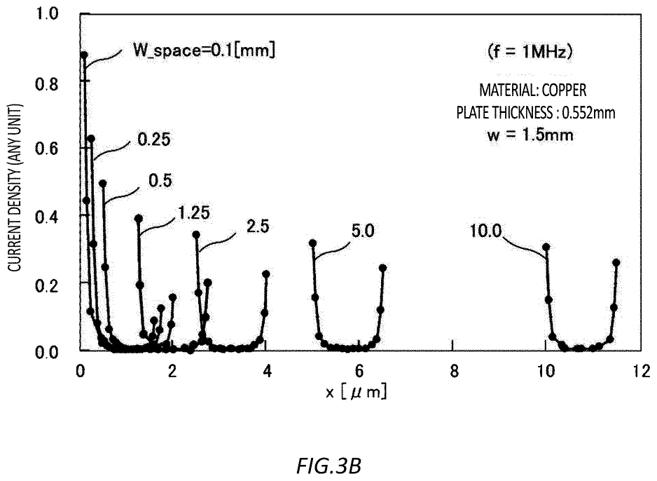

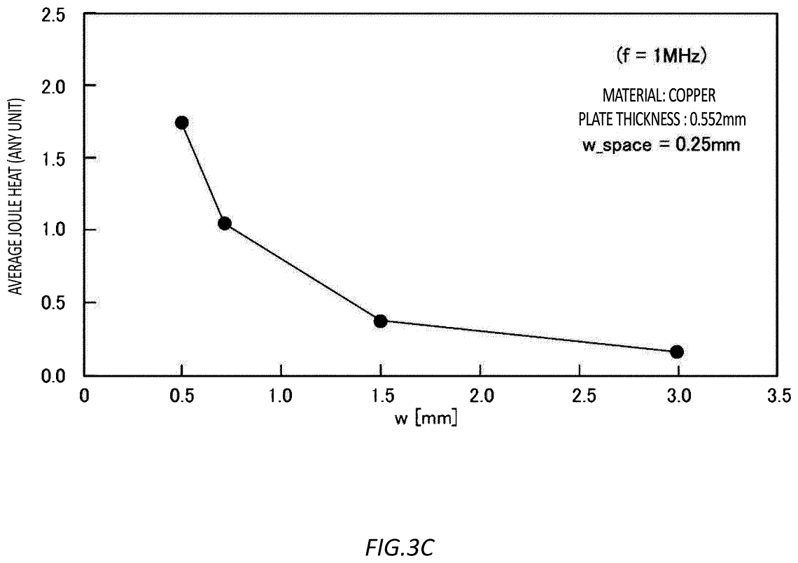

FIG. 3A shows a definition of a shape and a size of a conductor 140 (a width w of the conductor 140 and a width w_space of an internal region) for a simulation. The conductor 140 has two arm portions 142a, 142b and a turn portion 143. The two arm portions 142a, 142b are rectangular portions in which the sensor unit 20 of the magnetic sensor 30 is arranged, and simulate the first body portion 42a and the second body portion 42b of the conductor 40. The turn portion 143 is a part that connects the two arm portions 142a, 142b, and simulates the turn portion 43 of the conductor 40. The width w of the conductor 140, that is, the arm portion 142b; and the w_space that is half a distance between inner surfaces of the arm portions 142a, 142b which face each other (equal to an inner radius of curvature of the turn portion 143) are defined. The sensor unit 20 is set to be arranged at the center of the arm portion 142b in the vertical direction, and a current density field in this center part is obtained by a harmonic analysis using a finite element method.

FIG. 3B shows an analysis result of a density distribution of a surge current flowing through the conductor 140. Here, the surge current is simulated with a harmonic current of frequency 1 MHz, and further, a material of the conductor 140 is set to be copper, a plate thickness is set to 0.552 mm, and the width w of the arm portion 142b is set to 1.5 mm. In a case where the distance w_space is 10 mm, it can be seen that the current flowing through the arm portion 142b is concentrated on the inner surface and the outer surface of the arm portion 142b due to the skin effect, and almost no current flows in the center in a width direction. Here, there is no big difference in current density between the inner surface and the outer surface of the arm portion 142b. In a case where the distance w_space is 5 mm, the current flowing through the arm portion 142b is concentrated on the inner surface and the outer surface of the arm portion 142b due to the skin effect, and almost no current flows in the center in the width direction. There is no big difference in current density between the inner surface and the outer surface of the arm portion 142b.

However, in a case where the distance w_space is 2.5 mm or less, the current flowing through the arm portion 142b is concentrated on an inner surface of the arm portion 142b due to the proximity effect, and the current density on the inner surface is significantly greater than that on the outer surface of the arm portion 142b. At a distance w_space=0.1 mm, the current density on the inner surface of the arm portion 142b is about nine times that on the outer surface.

By bringing the two arm portions 142a, 142b closer together, in particular, by setting the distance w_space to be 2.5 mm or less, it is possible to concentrate the surge current on an inner surface side of the conductor 140 due to the proximity effect.

FIG. 3C shows an analysis result of an amount of heat generation (average Joule heat of a cross section) due to the surge current flowing through the conductor 140, with respect to the width w of the conductor 140. For the amount of heat generation, a current density j in the conductor 140 and a cross-sectional area S of the conductor 140 are used to calculate an amount of heat generation per unit cross-sectional area ∫j²dS/S. Here, the frequency of the surge current is set to 1 MHz, the material of the conductor 140 is set to be copper, the plate thickness is set to 0.552 mm, and the distance w_space is set to 0.25 mm. The smaller the width w of the conductor 140 is, the greater the amount of heat generation of the conductor 140 is. Accordingly, by decreasing the width w of the conductor 140, it is possible to locally increase the heat generation in the conductor 140.

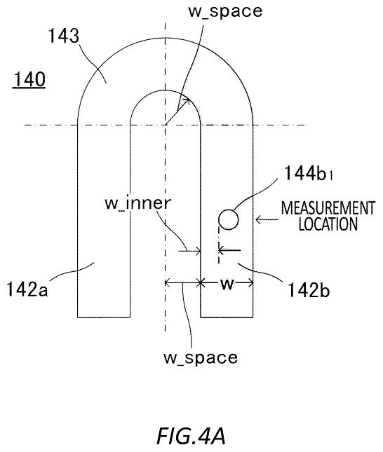

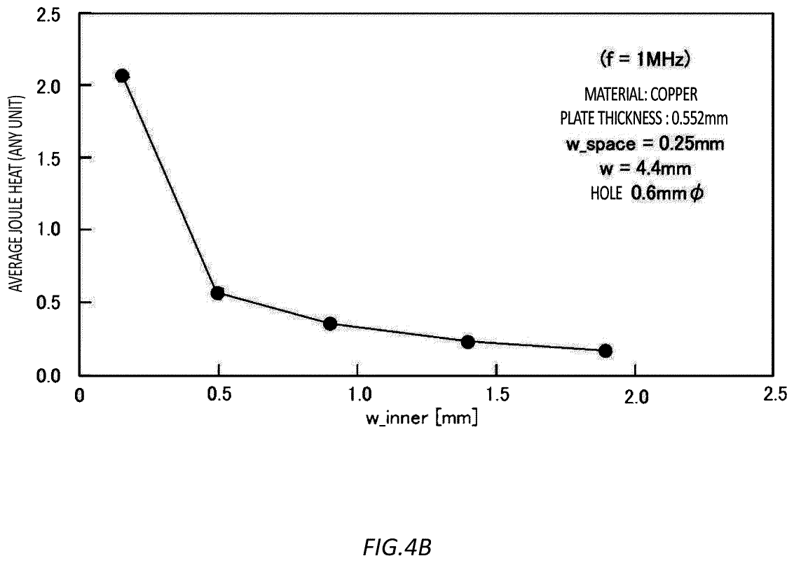

FIG. 4A shows a definition of a shape and a size of the conductor 140 (a width w of the conductor 140, a width w_space of an internal region, and a position w_inner of a hole) for a simulation. The conductor 140 has two arm portions 142a, 142b and the turn portion 143. The two arm portions 142a, 142b are rectangular portions in which the sensor unit 20 of the magnetic sensor 30 is arranged, and simulate the first body portion 42a and the second body portion 42b of the conductor 40. The turn portion 143 is a part that connects the two arm portions 142a, 142b, and simulates the turn portion 43 of the conductor 40. The width w of the conductor 140, that is, the arm portion 142b; and the w_space that is half a distance between inner surfaces of the arm portions 142a, 142b which face each other (equal to an inner radius of curvature of the turn portion 143) are defined. One hole 144b₁ of a circular shape is arranged at the center of the arm portion 142b in the vertical direction, and a distance w_inner from the inner surface of the arm portion 142b to the hole 144b₁ is defined, and the amount of heat generation in this center part is analyzed using the finite element method.

FIG. 4B shows an analysis result of an amount of heat generation (average Joule heat of a cross section) due to the surge current flowing through the conductor 140, with respect to the position w_inner of the hole 144b₁ in the conductor 140. For the amount of heat generation, the current density j in the conductor 140 and the cross-sectional area S of the conductor 140 are used to calculate the amount of heat generation per unit cross-sectional area ∫j²dS/S.

Here, the frequency of the surge current is set to 1 MHz, the material of the conductor 140 is set to be copper, the plate thickness is set to 0.552 mm, the width w of the arm portion 42b is set to 4.4 mm, the distance w_space is set to 0.25 mm, and the hole 144b₁ is set to have a circular shape with a diameter of 0.6 mm. The smaller the position w_inner of the hole 144b₁ is, the greater the amount of heat generation of the conductor 140 is. Accordingly, by bringing the hole 144b₁ closer to the inner surface of the arm portion 142b, with respect to a certain width w of the conductor 140, it is possible to further localize the current distribution toward an inner surface side in the conductor 140, and further increase the heat generation in the conductor 140.

Therefore, in the current sensor 1 according to the present embodiment, in the top view, in a continuous cross section of the conductor 40 which perpendicularly intersects the inner contour surfaces (that is, inner surfaces) 44a₀, 44b₀ of the conductor 40, a cross-sectional area S1 of a continuous cross section that is defined between the inner contour surfaces 44a₀, 44b₀ of the conductor 40 in the parallel sections 44a, 44b, and inner surfaces of the holes 44a₁, 44b₁ of at least ones of the holes 44aᵢ, 44bᵢ (i=1 to I, where I is 1 or more), which are positioned closest to inner contour surface 44a₀, 44b₀ sides of the conductor 40, is set to be smaller than a cross-sectional area of another continuous cross section between the inner contour surfaces 44a₀, 44b₀ of the conductor 40 outside the parallel sections 44a, 44b, and the outer contour surfaces (that is, the outer surfaces) 44a₅, 44b₅ of the conductor 40, for example, a cross-sectional area S43 of the turn portion 43. In this manner, when the surge current (instantaneous great current) flows through the conductor 40, the current is concentrated in the continuous cross section S1 in the parallel sections 44a, 44b, due to the proximity effect; generates heat; and causes melting and breaking for a fuse function to be performed. The cross section S1 is positioned to be spaced apart from the first terminal portion 41a, the second terminal portion 41b, and the turn portion 43, and thus it is possible to prevent damages to the primary circuit that is arranged on one side (the lower side of the figure) of the first terminal portion 41a and the second terminal portion 41b in the vertical direction, and to the secondary circuit that is arranged on another side (the upper side of the figure) of the turn portion 43 in the vertical direction.

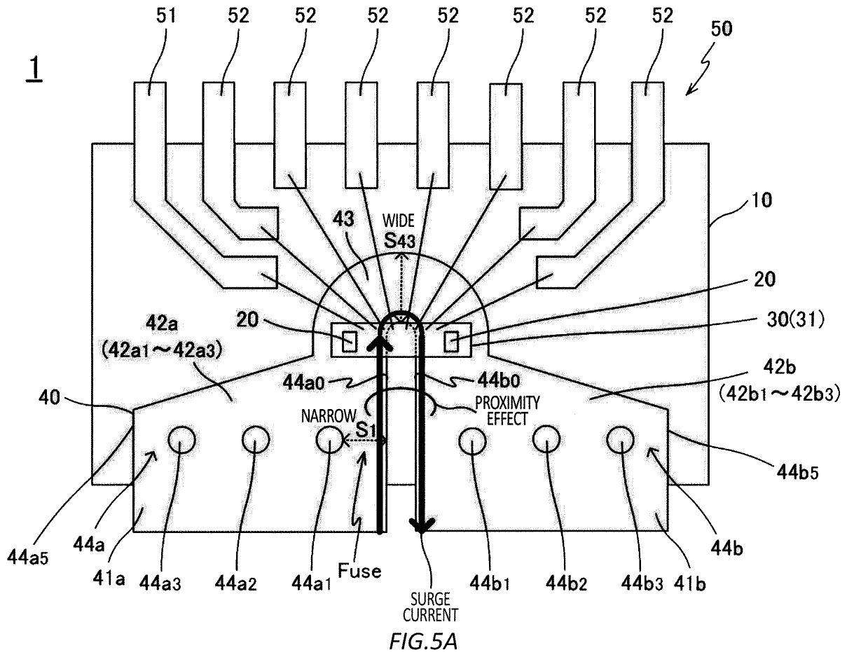

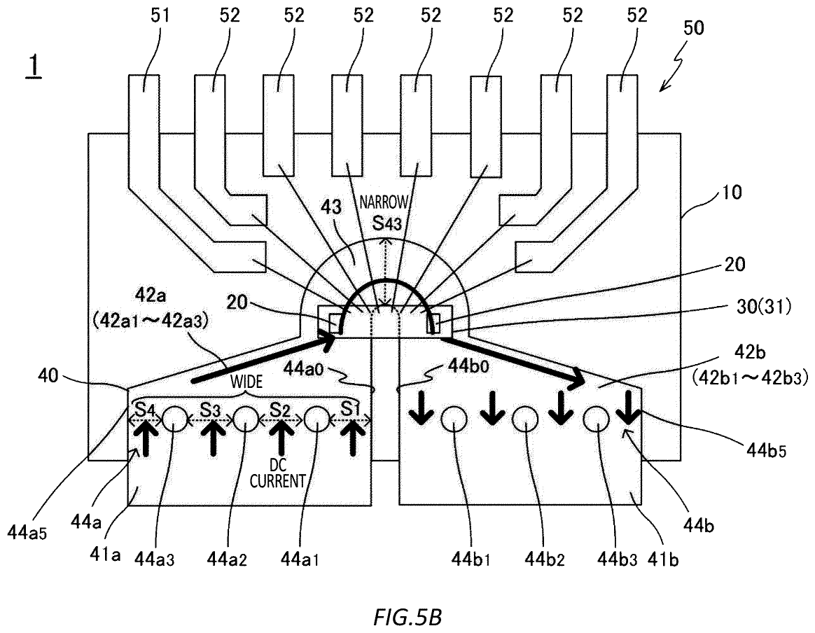

FIG. 5A shows the surge current that is concentrated and flowing inside the conductor 40 due to a proximity effect. By the analysis result described above, a distance between the contour surfaces of the first body portion 42a and the second body portion 42b which face each other is set to be 5 mm or less. In this manner, the surge current enters the conductor 40 from the first terminal portion 41a; is concentrated near the inner surface of the first body portion 42a (the surface of the right side of the figure) and flows upward in the figure; passes via a region near the inner surface of the turn portion 43, and changes a direction; is concentrated near the inner surface of the second body portion 42b (the surface of the left side of the figure) and flows downward in the figure; and is output from the second terminal portion 41b. In this way, due to the proximity effect, the flow of the surge current can be localized in a narrow region near the inner surfaces of the first body portion 42a and the second body portion 42b such that the heat generation is increased only in that localized region.

Further, by bringing the holes 44a₁, 44b₁ in the parallel sections 44a, 44b closer to the inner surfaces of the first body portion 42a and the second body portion 42b (for example, w_inner is set to be 0.5 mm or less), respectively, the flow of the surge current can be further localized in the narrow region near the inner surfaces of the first body portion 42a and the second body portion 42b in the parallel sections 44a, 44b such that the heat generation is further increased in that localized region. In this manner, the parallel section 44a of the first body portion 42a and/or the parallel section 44b of the second body portion 42b is able to perform the fuse function, and to prevent the damages to the primary circuit and the secondary circuit.

Therefore, in the current sensor 1 according to the present embodiment, in the top view, a continuous cross section which perpendicularly intersects inner contour surfaces 44a₀, 44b₀ of the conductor 40 outside the parallel sections 44a, 44b, and which is between the inner contour surfaces 44a₀, 44b₀ of the conductor 40 and the outer contour surfaces 44a₅, 44b₅ of the conductor 40, is set as a cross section in which there exists a continuous cross section that: is on a single plane perpendicularly intersecting the inner contour surfaces 44a₀, 44b₀ of the conductor 40 between the inner contour surfaces 44a₀, 44b₀ of the conductor 40 in the parallel sections 44a, 44b, and the outer contour surfaces 44a₅, 44b₅ of the conductor 40; and has a cross-sectional area smaller than a total cross-sectional area S1+S2+S3+S4 (S43<S1+S2+S3+S4) of a plurality of cross sections that are defined by the inner contour surfaces 44a₀, 44b₀, inner surfaces of at least ones of the holes 44aᵢ, 44bᵢ (i=1 to I, where I is 3 in the present example), and the outer contour surfaces 44a₅, 44b₅. This continuous cross section is, for example, the cross-sectional area S43 of the turn portion 43.

FIG. 5B shows a DC current flowing and spreading through the entire conductor 40. Regarding the DC current, the proximity effect contributes very little, and thus the DC current of the current to be measured that is input from the first terminal portion 41a spreads through the entire first body portion 42a; flows through the conductor 40 via the cross sections S1 to S4 between the holes 44aᵢ (i=1 to 3); enters the second body portion 42b via the turn portion 43; spreads through the entire second body portion 42b to flow through the conductor 40 via the cross sections S1 to S4 between the holes 44bᵢ (i=1 to 3); and is output from the second terminal portion 41b. By the total cross-sectional area S1+S2+S3+S4 of the plurality of cross sections in the parallel sections 44a, 44b being greater than the cross-sectional area S43 of the cross section of the turn portion 43, the high frequency component (refer to FIG. 5A) and the DC component (refer to FIG. 5B) of the current to be measured are frequency separated, and it is possible to provide the current sensor 1 which maintains a low resistance with respect to the DC current.

Further, in the top view, a cross-sectional area of a continuous cross section, for example, the cross-sectional area S43 of the turn portion 43, which perpendicularly intersects inner contour surfaces 44a₀, 44b₀ of the conductor 40 outside the parallel sections 44a, 44b, and which is between the inner contour surfaces 44a₀, 44b₀ of the conductor 40 and the outer contour surfaces 44a₅, 44b₅ of the conductor 40, is set as a cross section that has, between the inner contour surfaces 44a₀, 44b₀ of the conductor 40 in the parallel sections 44a, 44b, and the outer contour surfaces 44a₅, 44b₅ of the conductor 40, a cross-sectional area greater than each cross-sectional area S1, S2, S3, or S4 of a plurality of cross sections that are defined by the inner contour surfaces 44a₀, 44b₀, inner surfaces of at least ones of the holes 44aᵢ, 44bᵢ (i=1 to 3), and the outer contour surfaces 44a₅, 44b₅.

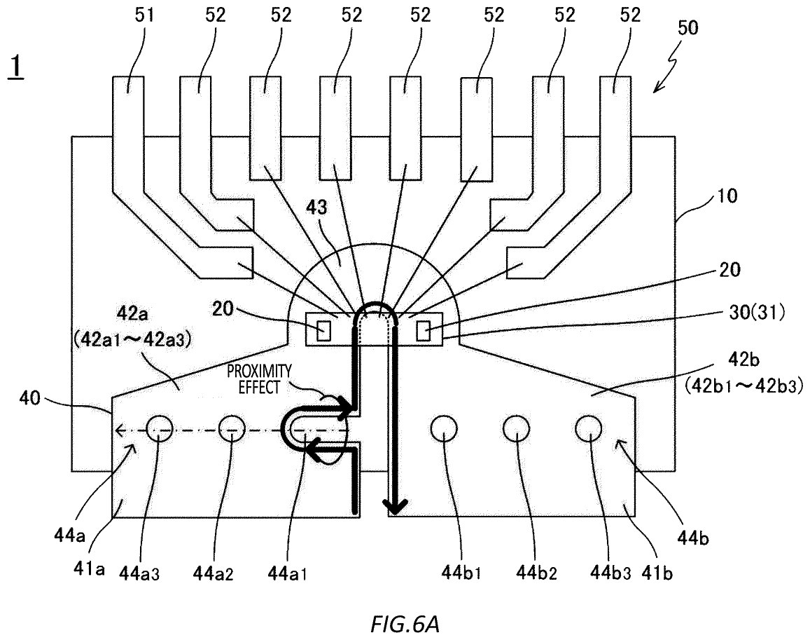

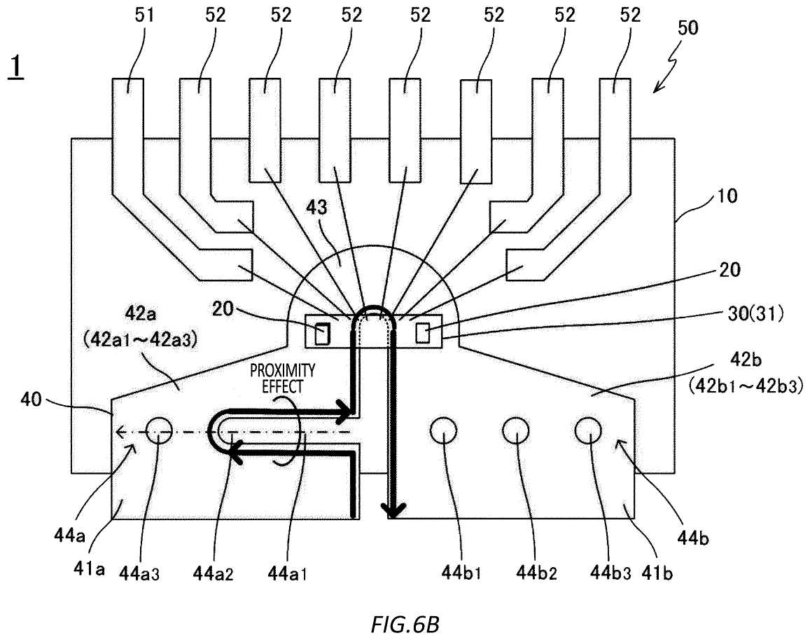

FIG. 6A and FIG. 6B show fuse operations of the conductor 40. The cross sections S1 to S4 between the holes 44aᵢ, 44bᵢ (i=1 to 3) in the parallel sections 44a, 44b being smaller than the cross sections outside the parallel sections 44a, 44b, whereby when the excessive surge current flows through the conductor 40, the current is concentrated in the cross section S1 in the parallel section 44a due to the proximity effect (refer to FIG. 5A) and generates the heat, and as shown in FIG. 6A, the conductor 40 is melted at the cross section S1 in the parallel section 44a. In this manner, in the conductor 40, a slit is formed to extend from the inner contour surface 44a₀ of the conductor 40 in the parallel section 44a to the hole 44a₁. The surge current is concentrated near both of inner surfaces of the slit due to the proximity effect and further generates the heat, and as shown in FIG. 6B, the conductor 40 is melted at the next cross section S2 in the parallel section 44a. In this manner, in the conductor 40, a slit is formed to extend from the inner contour surface 44a₀ of the conductor 40 in the parallel section 44a to the hole 44a₂. The surge current is concentrated near both of inner surfaces of the slit due to the proximity effect and further generates the heat; melts, in order in a direction of an arrow, the cross sections between the holes 44aᵢ (i=1 to 3) which are arranged side by side in the parallel section 44a; and ultimately melts and breaks the first body portion 42a in the parallel section 44a to be divided into two in the vertical direction. In this way, by arraying the holes 44aᵢ (i=1 to 3) in the horizontal direction in the parallel section, it is possible to induce melting and breaking of the conductor 40 in the horizontal direction and to avoid a progression of the melting and breaking toward the primary circuit that is arranged on one side (the lower side of the figure) of the first terminal portion 41a and the second terminal portion 41b in the vertical direction, or the secondary circuit that is arranged on another side (the upper side of the figure) of the turn portion 43 in the vertical direction.

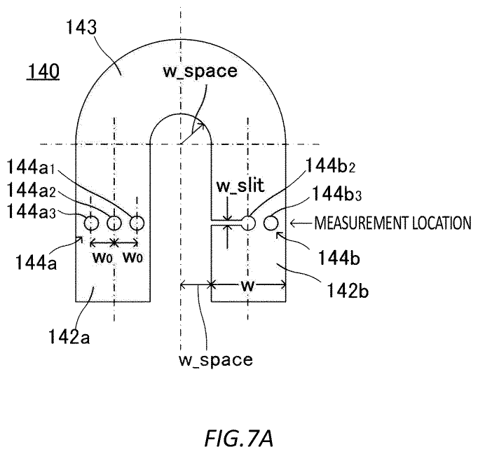

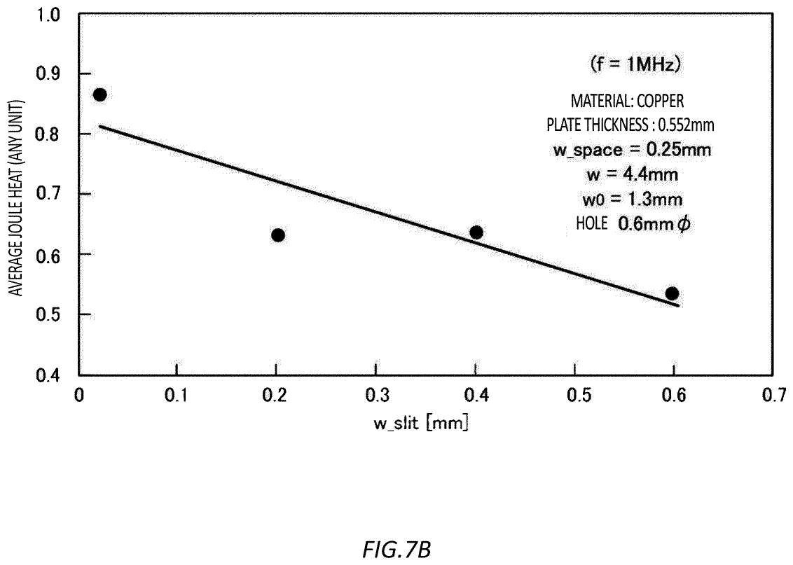

FIG. 7A shows a definition of a shape and a size of the conductor 140 (a width w of the conductor 140, a width w_space of an internal region, and a position w_inner of a hole, and a width w_slit of a slit) for a simulation. The conductor 140 has two arm portions 142a, 142b and the turn portion 143. The two arm portions 142a, 142b are rectangular portions in which the sensor unit 20 of the magnetic sensor 30 is arranged, and simulate the first body portion 42a and the second body portion 42b of the conductor 40. The turn portion 143 is a part that connects the two arm portions 142a, 142b, and simulates the turn portion 43 of the conductor 40. The width w of the conductor 140, that is, the arm portion 142b; and the w_space that is half a distance between inner surfaces of the arm portions 142a, 142b which face each other (equal to an inner radius of curvature of the turn portion 143) are defined. Two holes 144b₂, 144b₃ of circular shapes are arranged at the center of the arm portion 142b in the vertical direction, and the width w_slit of a slit that extends from the inner surface of the arm portion 142b to the hole 144b₂ is defined, and the amount of heat generation in this center part is analyzed using the finite element method. Three holes 144a₁ to 144a₃ of the circular shapes are arranged in the center of the arm portion 142a in the vertical direction. Distances w₀ between the holes 44b₂, 44b₃, and between the holes 44a₁ to 44a₃ are defined.

FIG. 7B shows an analysis result of an amount of heat generation (average Joule heat of a cross section) due to the surge current flowing through the conductor, with respect to the width w_slit of the slit in the conductor 140. For the amount of heat generation, the current density j in the conductor 140 and the cross-sectional area S of the conductor 140 are used to calculate the amount of heat generation per unit cross-sectional area ∫j²dS/S. Here, the frequency of the surge current is set to 1 MHz, the material of the conductor 140 is set to be copper, the plate thickness is set to 0.552 mm, the width w of the arm portion 142b is set to 4.4 mm, the distance w_space is set to 0.25 mm, the holes 144b₂, 144b₃ are set to have a circular shape with a diameter of 0.6 mm, and the distance w₀ between the holes is set to be 1.3 mm. The smaller the width w_slit of the slit is, the greater the amount of heat generation of the conductor 140 is.

Therefore, the holes 44aᵢ, 44bᵢ (i=1 to I, where I is 3 in the present example) have an approximately circular shape, an approximately elliptical shape, or an approximately rectangular shape in the top view; and in the vertical direction, have a width of 5 mm or less, preferably 2 mm, further preferably 1 mm, and still further preferably 0.6 mm or less, 0.5 mm or less, 0.4 mm or less, 0.3 mm or less, 0.2 mm or less, or 0.1 mm or less. It should be noted that the width of the holes 44aᵢ, 44bᵢ (i=1 to I, where I is 3 in the present example) in the vertical direction is preferably greater than or equal to a thickness of the conductor 40 to ensure workability of the conductor 40. Here, the thickness of the conductor 40 is, for example, 1 mm, 0.6 mm, 0.5 mm, 0.4 mm, 0.3 mm, 0.2 mm, or 0.1 mm.

Here, the holes 44aᵢ, 44bᵢ (i=1 to I, where I is 3 in the present example) do not need to be arrayed in a linear shape in the horizontal direction, and may be arrayed to face each other at least partially in the horizontal direction, that is, for regions thereof to partially overlap with each other when viewed in the horizontal direction. Alternatively, as long as the melting and breaking of the conductor 40 proceeds in the horizontal direction as a whole, the array may be made in a staggered pattern, for example. In this way, for a slit part formed by the melting and breaking of the conductor 40 in the cross section of parallel sections 44a, 44b, the surge current can further be concentrated near the inner surface of the slit by the proximity effect, to lead the melting and breaking of the conductor 40 in the horizontal direction in which the holes 44aᵢ, 44bᵢ (i=1 to I, where I is 3 in the present example) are arrayed in the parallel sections 44a, 44b.

It should be noted that the number I of the holes 44aᵢ, 44bᵢ (i=1 to I) and the distance between them may be arbitrarily determined as long as the melting and breaking of the conductor 40 proceeds in the horizontal direction as a whole; however, for example, the distance preferably increases in order of the distance from the inner contour surfaces 44a₀, 44b₀ of the conductor 40 to hole 44a₁ in the parallel sections 44a, 44b, the distance between holes 44a₁, 44a₂; the distance between holes 44a₂, 44a₃; and the distance between hole 44a₃ and the outer contour surfaces 44a₅, 44b₅ of the conductor 40 (that is, S1≤S2≤S3≤S4 in the cross-sectional areas). This makes it possible to lead the melting and breaking of the conductor 40 in the parallel sections 44a, 44b, from the inner contour surfaces 44a₀, 44b₀ of the conductor 40 to the outer contour surface 44a₅, 44b₅.

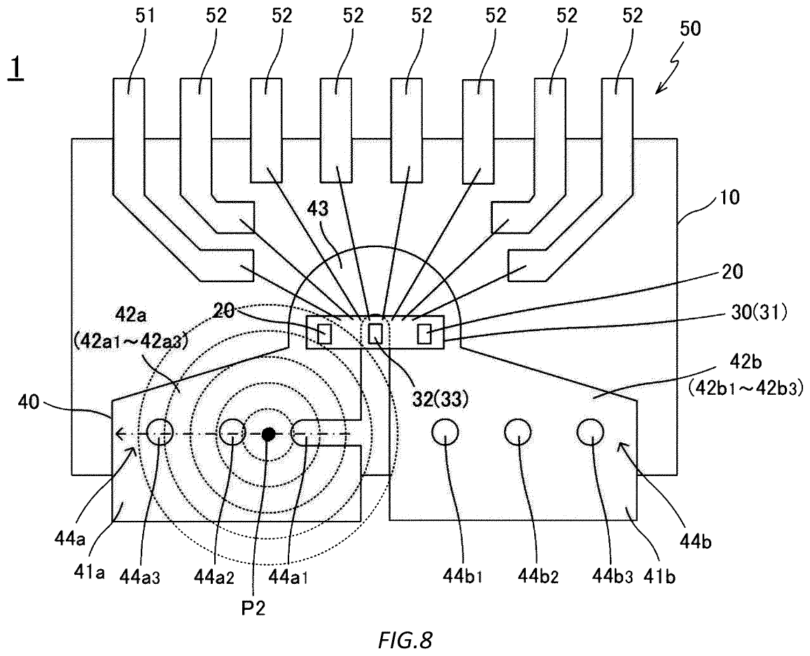

FIG. 8 shows an internal configuration of the current sensor 1 having a fault sensing function, in the top view. The magnetic sensor 30 further includes: a thermometer 32 arranged to be spaced apart from each of the two sensor units 20 on the substrate 31; and an electronic circuit 33 which receives respective measurement results of the temperatures of the two sensor units 20 and the thermometer 32. In the present example, the thermometer 32 is arranged at the center of the two sensor units 20. Here, the substrate 31 is arranged at least partially in the turn portion 43 of the conductor 40, the first connection portion 42a₂, and the second connection portion 42b₂. From the parallel sections 44a, 44b, distances to the two sensor units 20, and the thermometer 32 are different from each other. Here, by using a temperature characteristic of a resistance value of the magnetoelectric conversion element, for example, it is also possible to use the two sensor units 20 as thermometers.

The electronic circuit 33 independently monitors the temperatures by the two sensor units 20 and the thermometer 32, and sends a signal to the secondary circuit 3 via the plurality of signal terminals 50, for example, when the temperature difference between the two sensor units 20 and the thermometer 32 exceeds a threshold value. Under normal conditions, the temperature in current sensor 1 is determined by an external temperature and the heat generated by the current to be measured (the DC component or a low frequency component) flowing through the conductor. A temperature gradient in the package 10 caused by these factors is small. Here, when the surge current flows through the conductor 40, the fuse function is activated; and for example, the cross section (for example, the cross section S1) in the parallel section 44a is melted and broken and a slit that extends from the inner surface 44a₀ of the conductor 40 to hole 44a₁, is formed. Then, the surge current is concentrated on a cross section P2 between holes 44a₁, 44a₂ in the parallel section 44a, and generates the heat, thereby rapidly increasing the temperature gradient in the package 10. Here, the distances to the two sensor units 20, and the thermometer 32, from the parallel section 44a, in particular, the cross section P2 are different from each other; a difference in respective measured temperatures occurs by the temperature gradient; and it can be determined that the fuse function is activated by the temperature difference exceeding a predetermined threshold temperature. The melting and breaking of the conductor 40 progresses, for example, on the order of 10 milliseconds, and thus by the electronic circuit 33 sensing the difference between the measured temperatures of the two sensor units 20 and the thermometer 32, it is possible to sense the activation of the fuse function and to sense abnormality in the sensor.

It should be noted that when a plurality of sensor units 20 are provided on the substrate 31, the thermometer 32 may not be provided. Note that the two sensor units 20 are arranged on the substrate 31 such that the distances from the parallel sections 44a, 44b are different from each other. The electronic circuit 33 can independently monitor the temperatures by the two sensor units 20, and can send a signal when the temperature difference between at least the two sensor units 20 exceeds a threshold value.

FIG. 9 shows an arrangement of the conductor 40, the dielectric layer 39, and the magnetic sensor 30, in the top view. The dielectric layer 39 is a member which insulates and protects the magnetic sensor 30 from the conductor 40, and is disposed between the conductor 40 and the magnetic sensor 30. The dielectric layer 39 may include either an organic layer or ceramic. It is possible to form the dielectric layer 39 by using, for example, polyimide, glass, paper, fluororesin (Teflon (registered trademark)), or silicon.

The magnetic sensor 30 is arranged on the conductor 40 via the dielectric layer 39, and a contour line of the dielectric layer 39 is positioned outside a contour line of the substrate 31 in the top view. To ensure the insulation, it is preferable that the contour line of the dielectric layer 39 is separated outwards from the contour line of the substrate 31, by 0.4 mm or more. In this manner, the dielectric layer 39 effectively insulates the magnetic sensor 30 from the conductor 40 without covering the entire upper surface of the conductor 40, and the dielectric layer 39 does not impede the heat dissipation of the conductor 40 and does not reduce a heat dissipation property of the conductor 40.

In addition, in the top view, the contour line of the dielectric layer 39 is positioned on the turn portion 43 side when viewed from the parallel sections 44a, 44b, that is, the dielectric layer 39 is arranged to be closer to the turn portion 43 than the parallel sections 44a, 44b. An ignition point of a material such as polyimide that forms the dielectric layer 39 is about 600° C., and is lower than a melting temperature (about 1000° C.) of metal such as copper that forms the conductor 40, and thus by separating the dielectric layer 39 from the parallel sections 44a, 44b in which the fuse function is activated, a safe design of the current sensor 1 is possible.

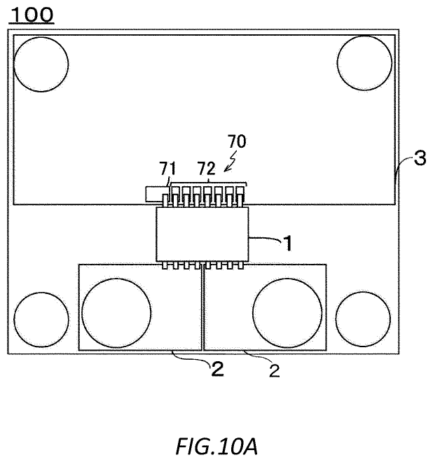

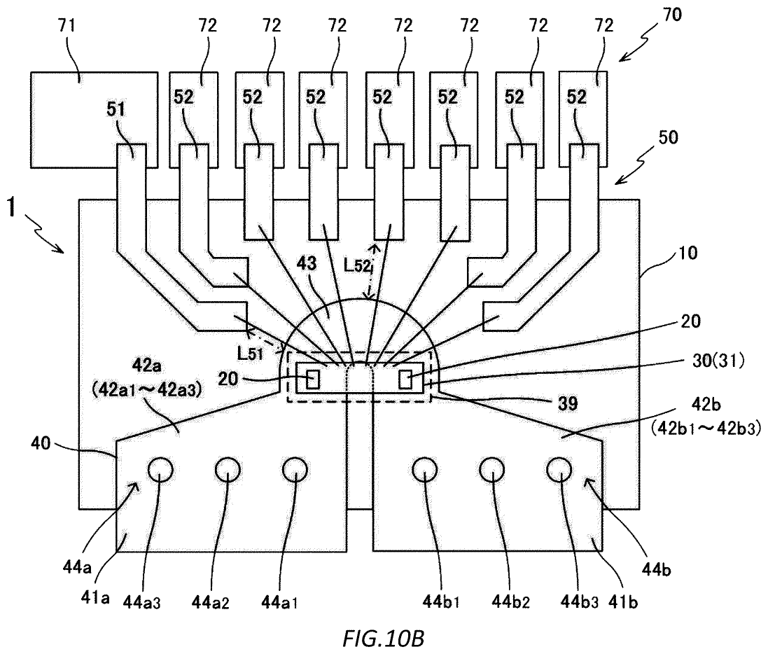

FIG. 10A shows a configuration of the mounting substrate 100 on which the current sensor 1 is mounted, in the top view. The mounting substrate 100 is a substrate including the current sensor 1, a primary circuit 2, and the secondary circuit 3. In the mounting substrate 100, the current to be measured is input from the primary circuit 2 to the current sensor 1, and the output signal of the current sensor 1 is output to the secondary circuit 3 via the plurality of signal terminals 50. It should be noted that the current sensor 1 is configured as described above.

The primary circuit 2 is a circuit which inputs the current to be measured to the current sensor 1, and is connected to the first terminal portion 41a and the second terminal portion 41b of the conductor 40 of the current sensor 1.

The secondary circuit 3 is a circuit which is operated in response to the output signal of the current sensor 1, and includes a plurality of footprints 70 that are respectively connected to a plurality of circuits (not shown). The plurality of footprints 70 are respectively connected to the plurality of signal terminals 50 (refer to FIG. 10B); and the output signal of the current sensor 1 is transmitted to each of the plurality of circuits via the plurality of signal terminals 50. The plurality of footprints 70 include a footprint 71 which is connected to one signal terminal 51 of the plurality of signal terminals 50, and footprints 72 which are connected to seven signal terminals 52.

FIG. 10B shows an arrangement of the current sensor 1 and the plurality of footprints 70, in the top view. As described above, the one signal terminal 51 and the seven signal terminals 52 of the plurality of signal terminals 50 are respectively connected to the one footprint 71 and the seven footprints 72 among the plurality of footprints 70. Here, the one signal terminal 51 of the plurality of signal terminals 50 is closer to the turn portion 43 than another signal terminal 52. A distance L51 from the signal terminal 51 to the turn portion 43 is smaller than a distance L52 from another signal terminal 52 to the turn portion 43. This makes it possible for the heat generated in the turn portion 43 to be dissipated to an outside of the package 10, via the signal terminal 51 which is closest to the turn portion 43 among the plurality of signal terminals 50. It should be noted that the distance L51 from the signal terminal 51 to the turn portion 43 is preferably 0.4 mm or more to ensure the insulation between the conductor 40 and the secondary circuit 3.

It should be noted that the signal terminal 51 may be a GND terminal. By the signal terminal 51 closest to the turn portion 43 being the GND terminal, when an electric arc occurs in the turn portion 43, it is possible to induce a discharge of electricity from the close signal terminal 51 to the GND, thereby suppressing the damage to the plurality of circuits on the secondary circuit 3 to which another signal terminal 52 is connected.

In addition, when the current sensor 1 is mounted on the mounting substrate 100, the signal terminal 51 is connected to the footprint 71 which has a greater area than that of the footprint 72 on the mounting substrate 100 to which another signal terminal 52 is connected. In this manner, by the footprint 71 on the mounting substrate 100 to which the signal terminal 51 is connected, having an area greater than the footprint 72 to which another signal terminal 52 is connected, it is possible for the signal terminal 51, to which the heat is transferred from the turn portion 43, to have a greater heat dissipation area and dissipate the heat efficiently, and it is possible to enhance a heat dissipation property of the turn portion 43 and prevent a fault due to a heat accumulation. It should be noted that the footprint 71 preferably has an area 1.5 to 40 times that of another footprint 72. In this way, it is possible to enhance the heat dissipation of the turn portion 43 and enhance the fuse function of the conductor 40 in the parallel sections 44a, 44b.

As described above, the current sensor 1 according to the present embodiment includes: the conductor 40 having the first terminal portion 41a for inputting the current, and the second terminal portion 41b for outputting the current which are arranged on one side in a first axial direction, the second terminal portion 41b being spaced apart from the first terminal portion 41a in a second axial direction intersecting the first axial direction, the turn portion 43 which is arranged on another side in the first axial direction with respect to the first terminal portion 41a, the first body portion 42a which connects one end of the turn portion 43 to the first terminal portion 41a, and the second body portion 42b which is spaced apart from the first body portion 42a in the second axial direction, to connect another end of the turn portion 43 to the second terminal portion 41b; the magnetic sensor 30 which is arranged on the conductor 40 or near the conductor 40; and the package 10 which encapsulates the turn portion 43, the first body portion 42a, the second body portion 42b of the conductor 40, and the magnetic sensor 30, and which exposes the first terminal portion 41a and the second terminal portion 41b, in which at least one of the first body portion 42a or the second body portion 42b includes the parallel sections 44a, 44b provided with at least one hole, and when viewed from a third direction intersecting each of the first axial direction and the second axial direction, in the continuous cross section of the conductor 40 which perpendicularly intersects the inner contour surface of the conductor 40, a cross-sectional area S1 of a continuous cross section that is defined between the inner contour surfaces of the conductor 40 in the parallel sections 44a, 44b, and inner surfaces of the holes 44a₁, 44b₁ of at least ones of the holes, which are positioned closest to an inner contour surface side of the conductor, is smaller than a cross-sectional area of another continuous cross section between the inner contour surface of the conductor 40 outside the parallel sections 44a, 44b and the outer contour surface of the conductor 40.

With this embodiment, in the top view, in a continuous cross section of the conductor 40 which perpendicularly intersects inner contour surfaces 44a₀, 44b₀ of the conductor 40, the cross-sectional area S1 of a continuous cross section that is defined between the inner contour surfaces 44a₀, 44b₀ of the conductor 40 in the parallel sections 44a, 44b provided with at least ones of the holes 44aᵢ, 44bᵢ (i=1 to 3) in at least one of the first body portion 42a or the second body portion 42b, and inner surfaces of the holes 44a₁, 44b₁ of at least ones of the holes 44aᵢ, 44bᵢ (i=1 to 3), which are positioned closest to inner contour surfaces 44a₀, 44b₀ sides of the conductor, is set to be smaller than a cross-sectional area of another continuous cross section between the inner contour surfaces 44a₀, 44b₀ of the conductor 40 outside the parallel sections 44a, 44b, and the outer contour surfaces 44a₅, 44b₅ of the conductor 40, whereby it is possible to provide the current sensor 1: in which when the surge current (instantaneous great current) flows through the conductor 40, the current is concentrated in the continuous cross section S1 in the parallel sections 44a, 44b, generates the heat, and causes the melting and breaking for the fuse function to be performed; in which the primary circuit that is arranged on one side (the lower side of the figure) of the first terminal portion 41a and the second terminal portion 41b in the vertical direction, is separated from the secondary circuit that is arranged on another side (the upper side of the figure) of the turn portion 43 in the vertical direction; and which has a high breakdown voltage.

In addition, in the current sensor 1 according to the present embodiment, the thickness of the conductor 40 is approximately constant, and when viewed from a third direction intersecting each of a first axial direction and a second axial direction, for a cross section made in a manner that from an inner contour line of the conductor 40, a straight line perpendicularly intersecting the contour line is drawn to a point of first intersecting another contour line of the conductor 40, a dimension (that is a width) of a cross section in the parallel sections 44a, 44b is smaller than a dimension of a cross section at a part of the conductor 40 outside the parallel sections 44a and 44b; and for a cross section made in a manner that from the inner contour line of the conductor 40, a straight line perpendicularly intersecting the contour line is drawn to an outer contour line of the conductor 40, there exists, at a part of the conductor 40 outside the parallel sections 44a, 44b, a cross section which has a dimension with a value smaller than a total value of dimensions of a plurality of cross sections in the parallel sections 44a, 44b. It should be noted that the thickness of the conductor 40 is approximately constant, a size of the dimension of the cross section of the conductor 40 is equal to the size of the cross-sectional area described above.

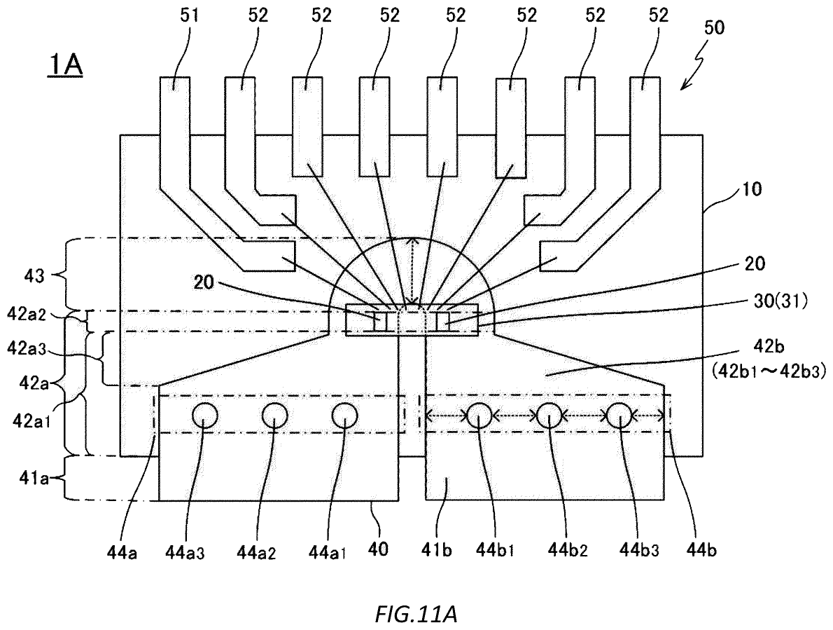

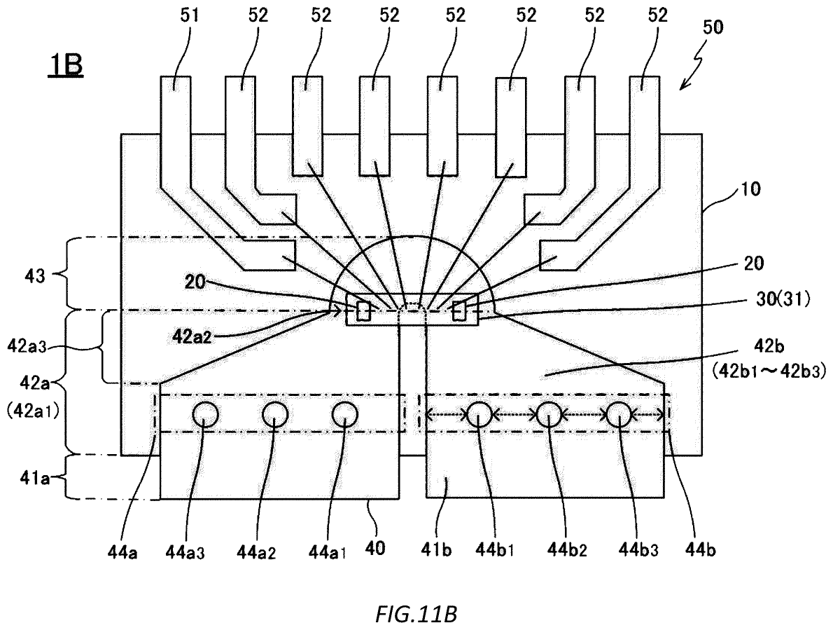

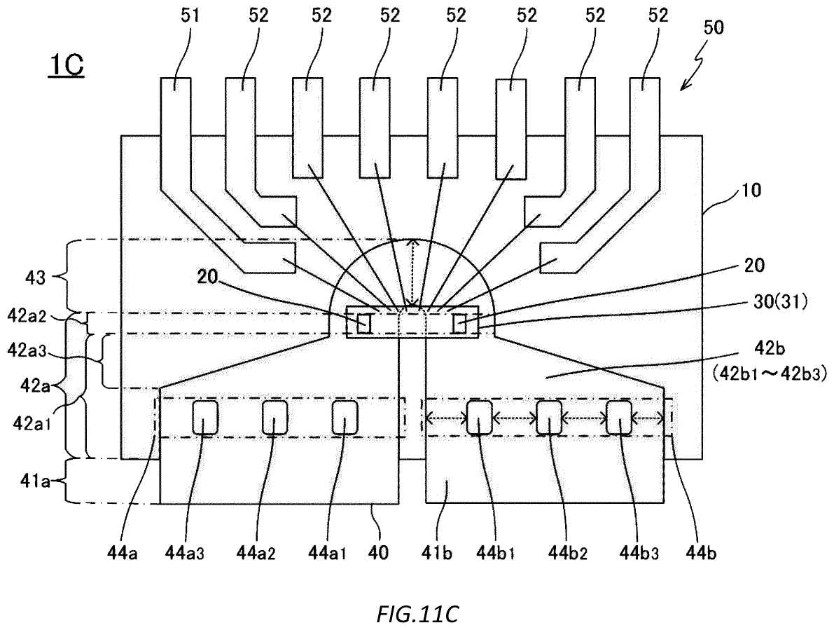

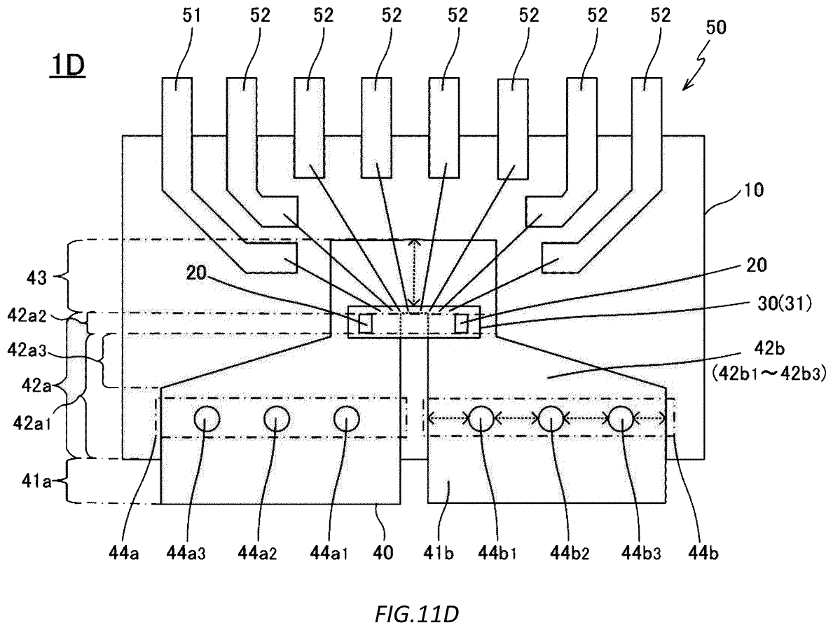

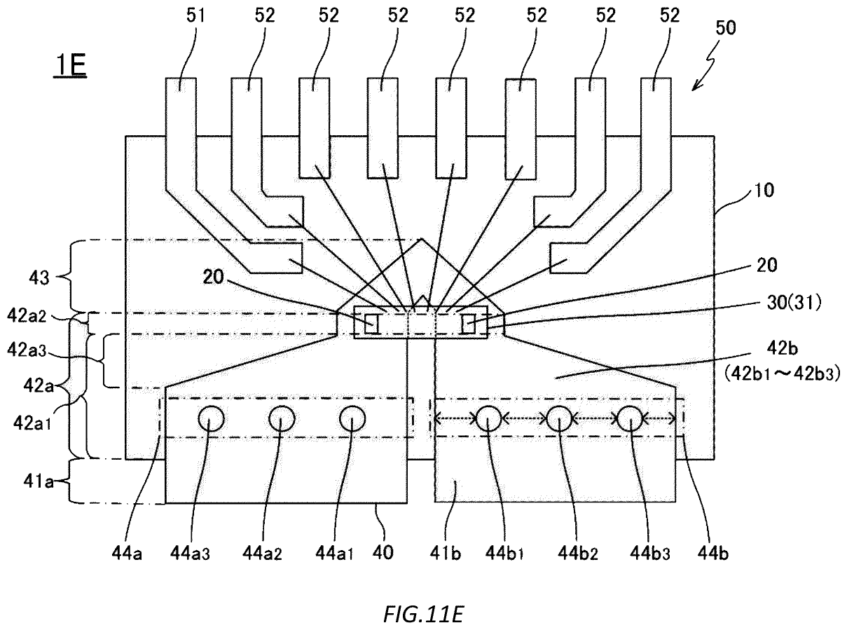

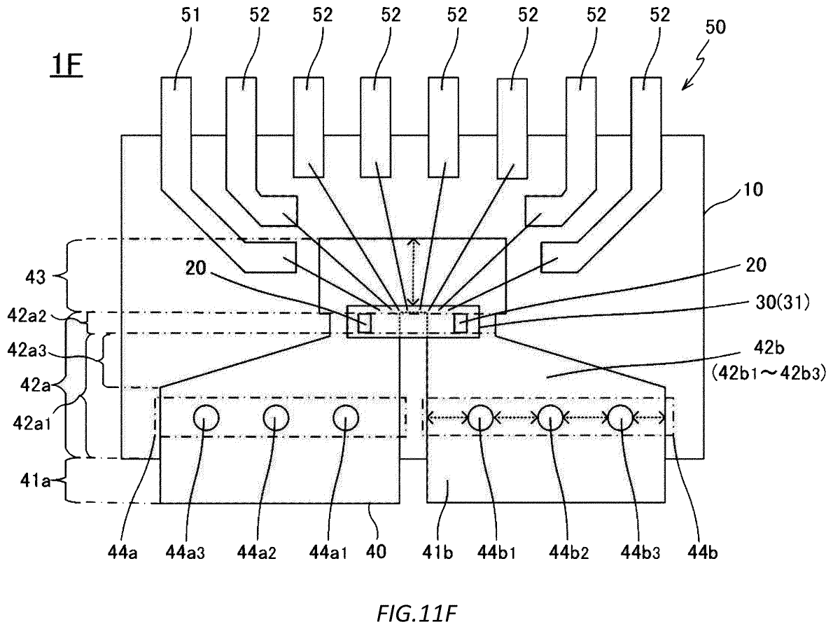

FIG. 11A to FIG. 11F show configurations of current sensors 1A, 1B, 1C, 1D, 1E, and 1F according to modified examples, in top views.

FIG. 11A shows the configuration of the current sensor 1A according to a first modified example. With respect to the above current sensor 1 shown in FIG. 1, each of the two sensor units 20 included in the magnetic sensor 30 is arranged to be closer to the center of the conductor 40. This makes it possible to suppress a generation of a common-mode voltage due to unevenness of a magnetic field distribution around the conductor 40.

FIG. 11B shows the configuration of the current sensor 1B according to a second modified example. With respect to the above current sensor 1 shown in FIG. 1, the lengths of the first connection portion 42a₂ and the second connection portion 42b₂ of the conductor 40 in the vertical direction are short; and are set, for example, to be a half of a width of the magnetic sensor 30 (the substrate 31) in the vertical direction, preferably one fifth, further preferably one tenth, still further preferably one hundredth, and still further preferably one thousandth, thereby making it is possible to decrease the resistance of the conductor 40 and to suppress the heat generation due to the DC current.

FIG. 11C shows the configuration of the current sensor 1C according to a third modified example. With respect to the above current sensor 1 shown in FIG. 1, the shapes of the holes 44aᵢ, 44bᵢ (i=1 to 3) which are arrayed in the parallel sections 44a, 44b of the conductor 40 are not limited to the circular shapes (or approximately circular shapes), and may be set to be elliptical shapes (or approximately elliptical shapes) or polygonal shapes including rectangular shapes (or approximately rectangular shapes).

FIG. 11D shows the configuration of the current sensor 1D according to a fourth modified example. With respect to the above current sensor 1 shown in FIG. 1, the turn portion 43, the first connection portion 42a₂, and the second connection portion 42b₂ of the conductor 40 may be formed to have a U shape. This makes it easy to process the conductor 40, and also makes it easy to design the signal terminal 50.

FIG. 11E shows the configuration of the current sensor 1E according to a fifth modified example. With respect to the above current sensor 1 shown in FIG. 1, the turn portion 43 of the conductor 40 may be formed to have an inverted V shape. This makes it possible to compactly design the turn portion 43.

FIG. 11F shows the configuration of the current sensor 1F according to a sixth modified example. With respect to the above current sensor 1 shown in FIG. 1, the turn portion 43, the first connection portion 42a₂, and the second connection portion 42b₂ of the conductor 40 may be formed to have an n shape. This makes it possible to increase an area of the turn portion 43 in the top view, and makes it possible to enhance the heat dissipation of the turn portion 43.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, steps, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

What is claimed is:

1. A current sensor comprising:
a conductor having a first terminal portion for inputting a current, and a second terminal portion for outputting the current which are arranged on one side in a first axial direction, the second terminal portion being spaced apart from the first terminal portion in a second axial direction intersecting the first axial direction, a turn portion which is arranged on another side with respect to the first terminal portion in the first axial direction, a first body portion which connects one end of the turn portion to the first terminal portion, and a second body portion which is spaced apart from the first body portion in the second axial direction, to connect another end of the turn portion to the second terminal portion;
a magnetic sensor which is arranged on the conductor or near the conductor; and
a package which encapsulates the turn portion, the first body portion, and the second body portion of the conductor, and the magnetic sensor, and which exposes the first terminal portion and the second terminal portion, wherein
the first body portion has a first connection portion which is connected to the turn portion,
the second body portion has a second connection portion which is connected to the turn portion,
at least a part of the magnetic sensor is arranged on at least one of the first connection portion or the second connection portion,
at least one of the first body portion or the second body portion includes a parallel section which is provided with at least one hole in at least one of a region between the first connection portion and the first terminal portion, or a region between the second connection portion and the second terminal portion, and
when viewed from a third direction intersecting each of the first axial direction and the second axial direction, in a continuous cross section of the conductor which perpendicularly intersects an inner contour surface of the conductor, a cross-sectional area of a first continuous cross section that is defined between the inner contour surface of the conductor in the parallel section, and an inner surface of a hole of the at least one hole which is positioned closest to an inner contour surface side of the conductor, is smaller than a cross-sectional area of another continuous cross section between the inner contour surface of the conductor outside the parallel section and an outer contour surface of the conductor.

2. The current sensor according to claim 1, wherein
when viewed from the third direction, in a continuous cross section which perpendicularly intersects the inner contour surface of the conductor outside the parallel section, and which is between the inner contour surface of the conductor and the outer contour surface of the conductor, there exists a second continuous cross section that: is on a single plane perpendicularly intersecting the inner contour surface of the conductor between the inner contour surface of the conductor in the parallel section, and the outer contour surface of the conductor; and has a cross-sectional area smaller than a total cross-sectional area of a plurality of cross sections that are defined by the inner contour surface, an inner surface of the at least one hole, and the outer contour surface.

3. The current sensor according to claim 1, wherein
at least one of the first body portion or the second body portion has a tapering shape portion which increases, from a connection portion with the turn portion, in a cross-sectional area of a cross section perpendicularly intersecting the inner contour surface of the conductor, from the another side in the first axial direction toward a direction of the one side.

4. The current sensor according to claim 1, wherein
the first body portion has the first connection portion which is connected to the turn portion,
the second body portion has the second connection portion which is connected to the turn portion,
at least one of the first connection portion or the second connection portion has an approximately rectangular shape when viewed from the third direction, and
at least a part of the magnetic sensor is arranged on at least one of the first connection portion or the second connection portion.

5. The current sensor according to claim 1, wherein
a distance between contour surfaces of the first body portion and the second body portion which face each other is 5 mm or less.

6. The current sensor according to claim 1, wherein
when viewed from the third direction, a continuous cross section which perpendicularly intersects the inner contour surface of the conductor outside the parallel section, and which is between the inner contour surface of the conductor and the outer contour surface of the conductor, has, between the inner contour surface of the conductor in the parallel section, and the outer contour surface of the conductor, a cross-sectional area greater than a cross-sectional area of each cross section of a plurality of cross sections that are defined by the inner contour surface, an inner surface of the at least one hole, and the outer contour surface.

7. The current sensor according to claim 6, wherein
the at least one hole includes a plurality of holes which are arranged side by side to face each other at least partially in the second axial direction.

8. The current sensor according to claim 1, wherein
the at least one hole has a width of 5 mm or less in the first axial direction.

9. The current sensor according to claim 4, further comprising:
a substrate which is arranged on the conductor via a dielectric layer, the substrate supporting the magnetic sensor, wherein
the substrate is arranged at least partially in the turn portion, the first connection portion, and the second connection portion,
the substrate is provided with a thermometer spaced apart from the magnetic sensor, and
from the parallel section, distances to the magnetic sensor and the thermometer are different from each other.

10. The current sensor according to claim 9, wherein
the substrate is provided with an electronic circuit which independently monitors temperatures by the magnetic sensor and the thermometer, and sends a signal when a temperature difference between the magnetic sensor and the thermometer exceeds a threshold value.

11. The current sensor according to claim 4, further comprising:
a substrate which is arranged on the conductor via a dielectric layer, the substrate supporting at least two magnetic sensors, each of which is the magnetic sensor, wherein
the substrate is arranged at least partially in the turn portion, the first connection portion, and the second connection portion, and
from the parallel section, distances to at least the two magnetic sensors are different from each other.

12. The current sensor according to claim 11, wherein
the substrate is provided with an electronic circuit which independently monitors temperatures by at least the two magnetic sensors, and sends a signal when a temperature difference between at least the two magnetic sensors exceeds a threshold value.

13. The current sensor according to claim 4, further comprising:
a substrate which is arranged on the conductor via a dielectric layer, the substrate supporting the magnetic sensor, wherein
the substrate is arranged at least partially in the turn portion, the first connection portion, and the second connection portion, and
when viewed from the third direction, a contour line of the dielectric layer is positioned outside a contour line of the substrate.

14. The current sensor according to claim 13, wherein
the dielectric layer includes either an organic layer or ceramic.

15. The current sensor according to claim 14, wherein
the dielectric layer includes polyimide or fluororesin, and
when viewed from the third direction, a contour line of the dielectric layer is positioned on a turn portion side when viewed from the parallel section.

16. The current sensor according to claim 1, further comprising:
a plurality of signal terminals which are spaced apart from the conductor to one side in the first axial direction, and which are encapsulated in the package with edges being exposed, wherein
at least one signal terminal of the plurality of signal terminals is closer to the turn portion than another signal terminal.

17. The current sensor according to claim 16, wherein
the at least one signal terminal is a GND terminal.

18. The current sensor according to claim 16, wherein
when the current sensor is mounted on a mounting substrate, the at least one signal terminal is connected to a footprint which has a greater area than that of a footprint on the mounting substrate to which another signal terminal of the plurality of signal terminals is connected.

19. The current sensor according to claim 1, wherein
a thickness of the conductor is approximately constant.

20. A current sensor comprising:
a conductor having a first terminal portion for inputting a current, and a second terminal portion for outputting the current which are arranged on one side in a first axial direction, the second terminal portion being spaced apart from the first terminal portion in a second axial direction intersecting the first axial direction, a turn portion which is arranged on another side with respect to the first terminal portion in the first axial direction, a first body portion which connects one end of the turn portion to the first terminal portion, and a second body portion which is spaced apart from the first body portion in the second axial direction, to connect another end of the turn portion to the second terminal portion;
a magnetic sensor which is arranged on the conductor or near the conductor; and
a package which encapsulates the turn portion, the first body portion, and the second body portion of the conductor, and the magnetic sensor, and which exposes the first terminal portion and the second terminal portion, wherein
at least one of the first body portion or the second body portion includes a parallel section which is provided with at least one hole, and
when viewed from a third direction intersecting each of the first axial direction and the second axial direction,
for a cross section made in a manner that from an inner contour line of the conductor, a straight line perpendicularly intersecting the contour line is drawn to a point of first intersecting another contour line of the conductor, a dimension of a cross section in the parallel section is smaller than a dimension of a cross section at a part of the conductor outside the parallel section; and
for a cross section made in a manner that from the inner contour line of the conductor, a straight line perpendicularly intersecting the contour line is drawn to an outer contour line of the conductor, there exists, at a part of the conductor outside the parallel section, a cross section which has a dimension with a value smaller than a total value of dimensions of a plurality of cross sections in the parallel section.
